(19) United States
(12) Patent Application Publication
(10) Pub. No.: US 2017/0292772 A1
(43) Pub. Date: Oct. 12, 2017

(54) REFRIGERATOR AND REFRIGERATOR MANUFACTURING METHOD

(71) Applicant: Dongbu Daewoo Electronics Corporation, Seoul (KR)

(72) Inventor: Bo Young KIM, Seoul (KR)

(21) Appl. No.: 15/365,780

(22) Filed: Nov. 30, 2016

(30) Foreign Application Priority Data
Apr. 12, 2016 (KR) 10-2016-0045017

(51) Int. Cl. F25D 23/02; C23C 14/24; C23C 14/20; C23C 14/34; B32B 17/06; B32B 7/12; B32B 15/08; F25D 11/02; B32B 37/12

(52) U.S. Cl. CPC F25D 23/02; F25D 11/02; C23C 14/24; C23C 14/20; B32B 37/12; B32B 17/06; B32B 7/12; B32B 15/08; C23C 14/34; F25D 2400/06; F25D 2400/18; B32B 2307/412; B32B 2509/10

(57) ABSTRACT

Embodiments of the present invention disclose a refrigerator having a main body including a storage space, a door coupled to the main body, and a glass film member covering at least a portion of a front surface of the door. The glass film member includes a glass panel, a protection layer bonded onto the glass panel, a film bonded to the protection layer, the film including a transparent film layer having a pattern formed on a surface thereof, a metal deposition layer deposited on the transparent film layer, and a coating layer coated on the transparent film layer.

### CROSS-REFERENCE TO RELATED APPLICATIONS

This application is based on and claims priority from Korean Patent Application No. 10-2016-0045017, filed on Apr. 12, 2016, the disclosure of which is incorporated herein in its entirety by reference.

### TECHNICAL FIELD

The present disclosure generally relates to refrigeration, and more specifically, to a refrigerator and a refrigerator manufacturing method.

### BACKGROUND

A refrigerator is an apparatus used to store food at a low temperature, for example, in a frozen state or a refrigerated state.

The interior of the refrigerator is typically cooled by a continuous supply of cold air. The cold air is generated by a heat exchange process using a refrigerant. The refrigerant is used in a freezing cycle consisting of compression, condensation, expansion and evaporation. Cold air supplied into the refrigerator is uniformly transferred to the interior of the refrigerator by convection, and the interior is used to store food at a desired temperature within the refrigerator.

In recent years, additional functional components have been added to refrigerators to enhance user convenience, such as water dispensers, in-home bars, ice-making devices, and the like. Moreover, new refrigerators often include new decorative components to enhance the visual appeal of the refrigerator. Thus, these refrigerators tend to have a distinguished design and are often attractive to consumers.

The refrigerator door of these refrigerators may have a unique color or printed pattern. In particular, the door is often manufactured using a metal plate to express a luxurious glossy or textured surface, which is appealing to consumers.

However, if the door is formed using a metal plate, fingerprints may be easily transferred to the door due to the specific characteristics of metal. This may mar the appearance of the refrigerator and make it difficult to maintain the refrigerator's clean and appealing aesthetic.

### SUMMARY

Embodiments of the present disclosure provide a refrigerator and a refrigerator manufacturing method, where the refrigerator's metallic appearance is improved by affixing a glass film member with enhanced fingerprint resistance and improved shock resistance to one or more doors of the refrigerator.

According to one embodiment, a refrigerator is disclosed including a main body having a storage space, a door disposed on a surface of the main body for selectively opening and closing the storage space, and a glass film member covering at least a portion of a front surface of the door. The glass film member includes a glass panel, a protection layer bonded onto the glass panel, and a film bonded onto the protection layer, where the film includes a transparent film layer having a pattern formed on a surface of the transparent film layer, a metal deposition layer deposited on the transparent film layer, and a coating layer coated on the transparent film layer.

According to another embodiment, a refrigerator is disclosed including a main body having a storage space, a door disposed on a surface of the main body, and a glass film member covering at least a portion of a front surface of the door. The glass film member includes a glass panel, and a film bonded to the glass panel, where the film includes a transparent film layer, a printing layer disposed on the transparent film layer, and a coating layer disposed on the transparent film layer, where the coating layer has a predetermined pattern.

### BRIEF DESCRIPTION OF THE DRAWINGS

FIG. 1 is a diagram illustrating an exemplary refrigerator according to one embodiment of the present disclosure.

FIG. 2 is an exploded diagram illustrating an exemplary door of the refrigerator illustrated in FIG. 1 according to one embodiment of the present disclosure.

FIG. 3 is a diagram illustrating a glass film member according to one embodiment of the present disclosure.

FIG. 4 is a flowchart illustrating an exemplary method for manufacturing a refrigerator provided with the glass film member illustrated in FIG. 3 according to one embodiment of the present disclosure.

FIGS. 5 and 6 are views illustrating an exemplary method of preparing a film of the glass film member illustrated in FIG. 3 according to one embodiment of the present disclosure.

FIG. 7 is a sectional view illustrating an exemplary glass film member according to another embodiment of the present disclosure.

FIG. 8 is a flowchart illustrating an exemplary method for manufacturing a refrigerator provided with the glass film member illustrated in FIG. 7 according to one embodiment of the present disclosure.

FIG. 9 is a view illustrating an exemplary method of preparing a film of the glass film member illustrated in FIG. 7 according to one embodiment of the present disclosure.

### DETAILED DESCRIPTION

In the following detailed description, reference is made to the accompanying drawings, which are incorporated herein. The illustrative embodiments described in the detailed description, drawings, and claims are not meant to be limiting. Other embodiments may be utilized, and other changes may be made, without departing from the spirit or scope of the subject matter presented here.

One or more exemplary embodiments of the present disclosure will be described more fully hereinafter with reference to the accompanying drawings, in which one or more exemplary embodiments of the disclosure can be easily determined by those skilled in the art. As those skilled in the art will realize, the described exemplary embodiments may be modified in various different ways, all without departing from the spirit or scope of the present disclosure, which is not limited to the exemplary embodiments described herein.

It is noted that the drawings are schematic and are not necessarily dimensionally illustrated. Relative sizes and proportions of parts in the drawings may be exaggerated or reduced in size, and a predetermined size is merely exemplary and not limiting. The same reference numerals designate the same structures, elements, or parts illustrated in two or more drawings in order to exhibit similar characteristics.

The exemplary drawings of the present disclosure illustrate ideal exemplary embodiments of the present disclosure in more detail. As a result, various modifications of the drawings are expected. Accordingly, the exemplary embodiments are not limited to a specific form of the illustrated region, and for example, may include modifications of form due to manufacturing.

The configuration and operation according to one embodiment of the present disclosure will now be described with reference to the accompanying drawings.

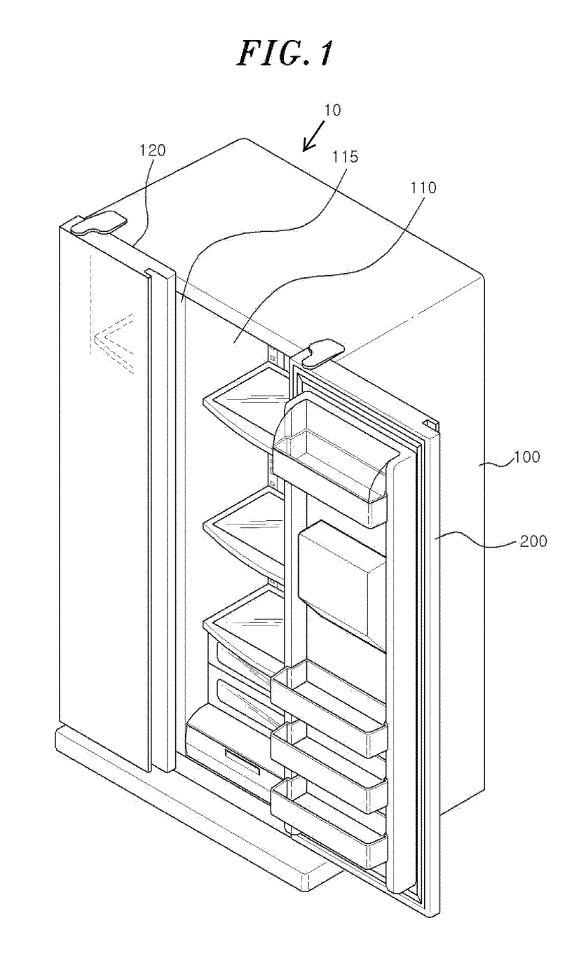

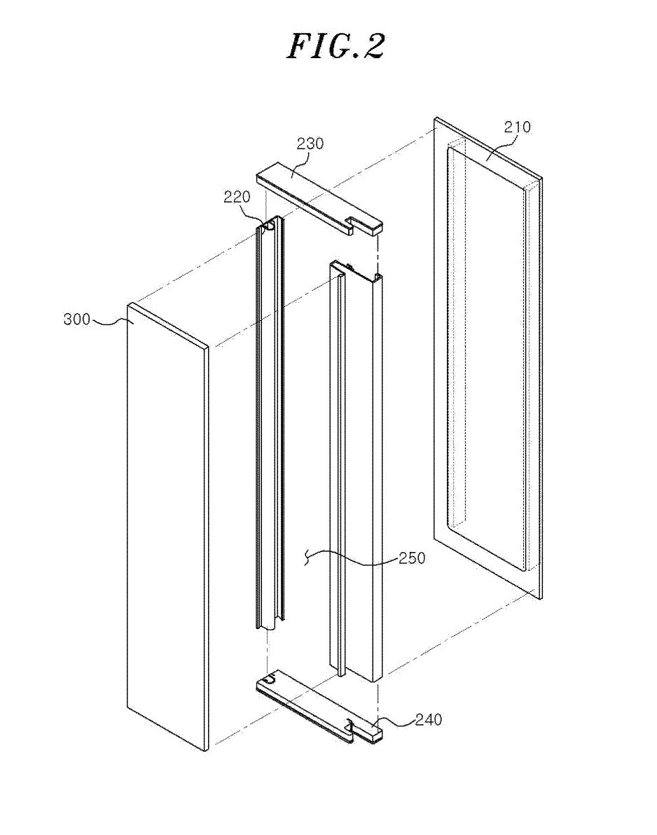

FIG. 1 is a diagram illustrating an exemplary refrigerator according to one embodiment of the present disclosure. FIG. 2 is an exploded diagram illustrating an exemplary door of the refrigerator illustrated in FIG. 1 according to one embodiment of the present disclosure.

Referring to FIGS. 1 and 2, the refrigerator 10 may include a main body 100 including a storage space, a door 200 coupled to the main body 100 for selectively opening and closing the storage compartment, and a glass film member 300 configured to cover at least a portion of a front surface of the door 200.

The main body 100 may include a storage space for storing food. Specifically, the main body 100 may include a refrigeration compartment 110 and a freezing compartment 120 divided by a vertical barrier 115, and a cold air generation compartment (not shown) disposed at a rear side of the refrigeration compartment 110 or the freezing compartment 120.

The refrigeration compartment 110 stores food in a refrigerated state using cold air generated in the cold air generation compartment. The internal space of the refrigeration compartment 110 may be sealed by the door 200.

The freezing compartment 120 stores food in a frozen state using cold air generated in the cold air generation compartment. The freezing compartment 120 may be separated from the refrigeration compartment 110 by the barrier 115. The internal space of the freezing compartment 120 may be sealed by the door 200.

The door 200 may be mounted to the main body 100 at an upper end and a lower end to seal the storage space, and may be mounted in a way that allows the door 200 to rotate about an edge of the door 200 for opening and closing the storage space, for example, using one or more hinges. A front surface of the door 200 may be at least partially covered by a glass film member 300.

A rear surface of the door 200 may be defined by a liner member 210. Side surfaces of the door 200 may be formed by a pair of side frames 220. An upper surface of the door 200 may be formed by an upper cap 230, and a lower surface of the door 200 may be defined by a lower cap 240.

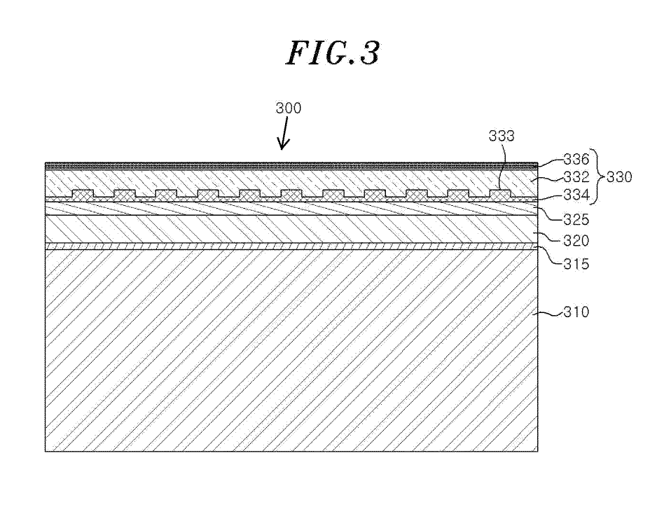

FIG. 3 is a diagram illustrating an exemplary glass film member according to one embodiment of the present disclosure.

Referring to FIG. 3, the glass film member 300 may include a glass panel 310, a protection layer 320 bonded to the glass panel 310 and a film 330 bonded onto the protection layer 320.

The glass panel 310 acts as a base layer for the glass film member 300 and may include, for example, reinforced glass having predetermined strength.

The protection layer 320 may be bonded onto the glass panel 310 and may include, for example, a poly vinyl chloride resin.

The glass panel 310 and the protection layer 320 may be bonded to each other by an adhesion layer 315 disposed between the glass panel 310 and the protection layer 320. The adhesion layer 315 may include, for example, an ultraviolet-curable resin including urethane, an acryl-based monomer, an acryl-based oligomer, a photo initiator, or additives for altering a physical property of the adhesion layer.

According to some embodiments, a thickness of the blades 300 is roughly between 10 μm and 20 μm to ensure that a bonding force between the adhesion layer 315 and the glass panel 310 is sufficiently strong.

According to some embodiments, the adhesion layer 315 has a haze value of less than 10 to ensure that a metal deposition layer 334 is visible from the outside of the film 330.

A bonding layer 325 may be formed on the protection layer 320. The bonding layer 325 is used to bond the film 330 to the protection layer 320. The bonding layer 325 may include, for example, an acryl-based resin, an acryl urethane-based resin, an epoxy-based resin, a polyurethane-based resin, a poly isocyanate-based resin, a polyester-based resin, an acrylate-based resin, an ethylene-vinyl acetate copolymer, a polyamide-based resin, a melamine-based resin, a synthetic resin-based resin or a polyvinyl alcohol-based resin.

According to some embodiments, the thickness of the bonding layer 325 is between 1 μm and 5 μm to strengthen a bond between the film 330 and the protection layer 320, and to prevent the thickness of the glass film member 300 from becoming unnecessarily large.

The film 330 may include a transparent film layer 332 having a predetermined pattern 333 on a lower surface thereof, a metal deposition layer 334 deposited by filling the pattern 333, and a coating layer 336 coated on the transparent film layer 332. According to some embodiments, the metal deposition layer 334 is deposited when the pattern 333 is filled.

The transparent film layer 332 may be made of, for example, a polyethylene terephthalate resin, a polyvinyl chloride resin, a polyethylene terephthalate glycol resin, a polypropylene resin, a polybutylene terephthalate resin, a polycarbonate resin, or a polymethyl methacrylate resin.

According to some embodiments, the thickness of the transparent film layer 332 is between 20 μm and 100 μm to ensure that the transparent film layer 332 is able to support the coating layer 336, and to ensure that the metal deposition layer 334 is sufficiently visible from outside of the film 330.

The film 330 may include a metal texture formed by the pattern 333 on a lower surface of the transparent film layer 332. The pattern 333 may be an embossed pattern, an engraved pattern, hairline pattern, or the like. For example, the pattern 333 may include at least one of: a fine irregularity pattern, a mirror pattern, an etching pattern, a vibration pattern, and a bead blast pattern.

According to some embodiments, the thickness of the pattern 333 is between 3 μm and 20 μm to enhance a metallic appearance of the film 330.

The metal deposition layer 334 may be deposited by filling the pattern 333 of the transparent film layer 332.

The metal deposition layer 334 may be observed through the coating layer 336 and the transparent film layer 332. In this way, the film 330 provides a texture or finish similar to metal and may look metallic in appearance.

The metal deposition layer 334 may highlight or enhance the pattern 333 of the transparent film layer 332 and make the transparent film layer 323 appear more metallic. The metal deposition layer 334 enables the image of the pattern 333 of the transparent film layer 332 to be visible in different colors depending on the viewing angle. This is because the wavelength of the light reflected from the surface of the metal deposition layer 334 is changed after passing through the pattern 333 of the transparent film layer 332 depending on the wavelength of incident light. For example, the metal deposition layer 334 may include titanium (Ti) and chromium (Cr). A relatively low oxidation degree minimizes oxidation of an end surface of the metal deposition layer 334 and improves chemical resistance of the film 330.

The metal deposition layer 334 may be a mono-layered metal film layer or a multi-layered metal film layer. When the multi-layered metal film layer is used, it is possible to present a specific color or texture, such as a shiny metallic appearance or texture.

The coating layer 336 may be applied to the transparent film layer 332. The coating layer 336 may include, for example, an ultraviolet-curable resin including urethane, an acryl-based monomer, an acryl-based oligomer, a photo initiator, and other additives for compensating for certain physical properties. The coating layer 336 may be disposed on an uppermost layer of the film 330 to increase surface hardness of the film 330. According to some embodiments, the surface of the coating layer 336 is substantially smooth to enhance fingerprint resistance and contamination resistance of the film 330.

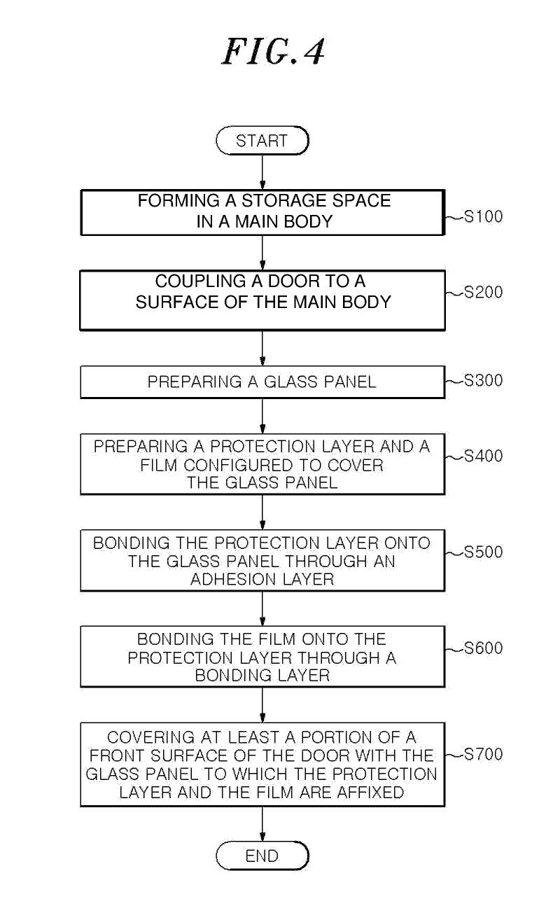

A method of manufacturing a refrigerator (e.g., refrigerator 10) will now be described with reference to FIGS. 4 to 6, according to embodiments of the present invention.

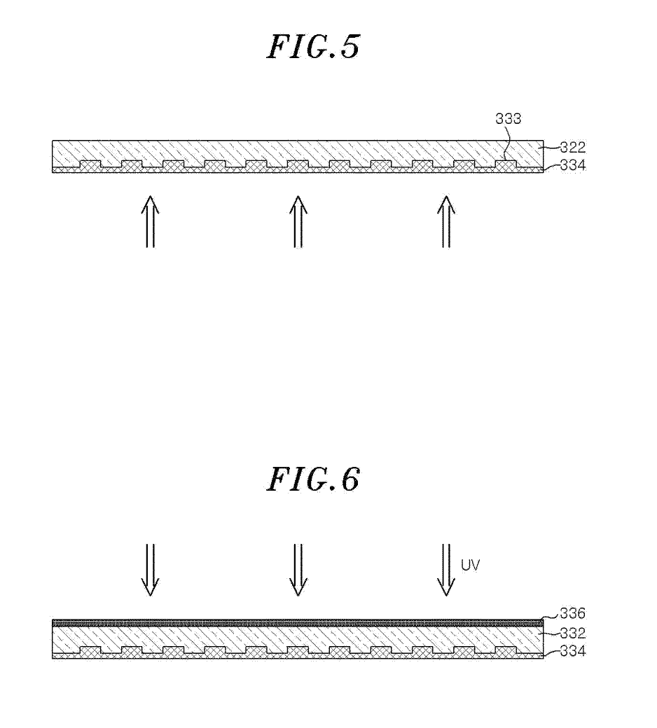

FIG. 4 is a flowchart illustrating an exemplary sequence of steps for performing a method for manufacturing a refrigerator provided with the glass film member illustrated in FIG. 3 according to embodiments of the present invention. FIGS. 5 and 6 are diagrams illustrating an exemplary sequence of steps for performing a method of preparing a film of the glass film member illustrated in FIG. 3 according to embodiments of the present invention.

A storage space is formed in a main body 100 (S100), and a door 200 configured to selectively open and close the storage space is coupled to the main body 100 (S200).

To install the door 200, a glass panel 310 is prepared (S300), and a protection layer 320, which covers the glass panel 310, and a film 330 are prepared (S400).

The step of preparing the film 330 will now be described with reference to FIGS. 5 and 6.

As illustrated in FIG. 5, the metal deposition layer 334 is deposited by filling the pattern 333 of the transparent film layer 332, where the pattern 333 is disposed on a lower surface of the transparent film layer 332.

The metal deposition layer 334 is formed by a sputtering process, a vacuum thermal deposition process or the like. For example, when the metal deposition layer 334 is formed using a sputtering process, the metal deposition has a thickness of about 0.70 optical density (OD) due to metal nano particles coated on a lower surface of the transparent film layer 332 in a plasma state. Alternatively, the metal deposition layer 334 may be formed using a vacuum thermal deposition process, where vacuum deposition is performed under a pressure of about 10⁻⁴ Torr to about 10⁻⁶ Torr and at a temperature of about 300° C. to about 800° C. However, the method of forming the metal deposition layer 334 is not limited thereto.

If a surface of the metal deposition layer 334 is exposed, the exposed surface may become oxidized. The metal deposition layer 334 may be separated from the transparent film layer 332 due to oxidation. According to some embodiments, the metal deposition layer 334 includes titanium (Ti) and/or chromium (Cr), which are relatively low in oxidation degree.

As illustrated in FIG. 6, an ultraviolet-curable resin is coated on the transparent film layer 332. Thereafter, ultraviolet rays irradiate the ultraviolet-curable resin, using an ultraviolet lamp (not shown), for example.

As the ultraviolet-curable resin is cured by the irradiation of the ultraviolet rays, the coating layer 336 is bonded to the transparent film layer 332.

The protection layer 320 is bonded onto the glass panel 310 through the adhesion layer 315 (S500). Then, the film 330 is bonded onto the protection layer 320 through the bonding layer 325 (S600).

At least a portion of the front surface of the door 200 is covered by the glass panel 310 to which the protection layer 320 and the film 330 are affixed (S700). According to some embodiments, the glass panel 310 to which the protection layer 320 and the film 330 are affixed includes the glass film member 300.

The glass film member 300, the side frames 220, the upper cap 230 and the lower cap 240 are fixed to a lower foaming jig (not shown). The liner member 210 is fixed to an upper foaming jig (not shown).

The lower foaming jig and the upper foaming jig are assembled together. A foaming liquid is injected into an internal space formed between the upper foaming jig and the lower foaming jig. The lower foaming jig and the upper foaming jig are heated. Thereafter, the door 200 is mounted to the main body 100, using a hinge, for example, thereby coupling the door 200 to the main body 100 so that the door 200 can selectively open and close the storage space of the main body 100.

The glass film member 300 covers at least a portion of the front surface of the door 200 of the refrigerator 10 illustrated in FIGS. 1 and 2.

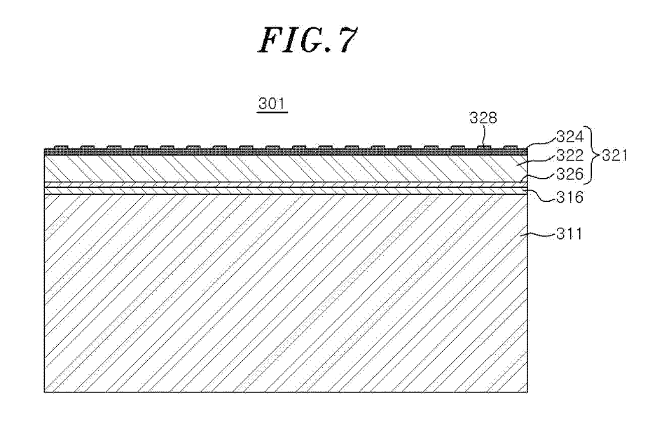

An exemplary glass film member 301 according to another embodiment of the present disclosure will now be described with reference to FIG. 7.

FIG. 7 is a diagram illustrating an exemplary glass film member according to embodiments of the present disclosure.

The film 321 may include a transparent film layer 322, a printing layer 326 disposed on a lower surface of the transparent film layer 322 and a coating layer 324 disposed on the transparent film layer 322.

Other than the lower surface structure, the transparent film layer 322 is substantially similar to the transparent film layer 332 described with reference to FIG. 3. Thus, duplicate descriptions thereof will be omitted. For example, the transparent film layer 322 may have a flat lower surface structure. According to some embodiments, a predetermined pattern is not formed on the lower surface of the transparent film layer 322 because a hair line 328 is formed on the upper surface of the coating layer 324, which will be described later.

The printing layer 326 may be disposed on the lower surface of the transparent film layer 322. The printing layer 326 may be printed on the entire lower surface of the transparent film layer 322 using pigments of different colors. Alternatively, a specific pattern may be printed.

In this regard, the printing layer 326 may be recognized visually through the coating layer 324 and the transparent film layer 322. This enables the glass film member 301 to express different colors or specific patterns.

The coating layer 324 may be disposed on the transparent film layer 322, and may include, for example, an ultraviolet-curable resin. The coating layer 324 may have a hair line 328 disposed on an upper surface thereof.

In this regard, the hair line 328 may be at least one selected from a group consisting of a vertical hair line pattern, a horizontal hair line pattern, a multi-directional hair line pattern, a non-directional hair line pattern and a circular hair line pattern.

The thickness of the hair line 328 may be about 5 μm to about 15 μm. If the thickness of the hair line 328 is smaller than about 5 μm, fine hair lines observed on a metal surface are barely visible, and may not be visible at all. This allows the printing layer to give an appearance of metal. If the thickness of the hair line 328 is larger than about 15 μm, the hair line 328 may not appear metallic. Furthermore, this may adversely affect the physical properties (e.g., strength or durability) of the final product.

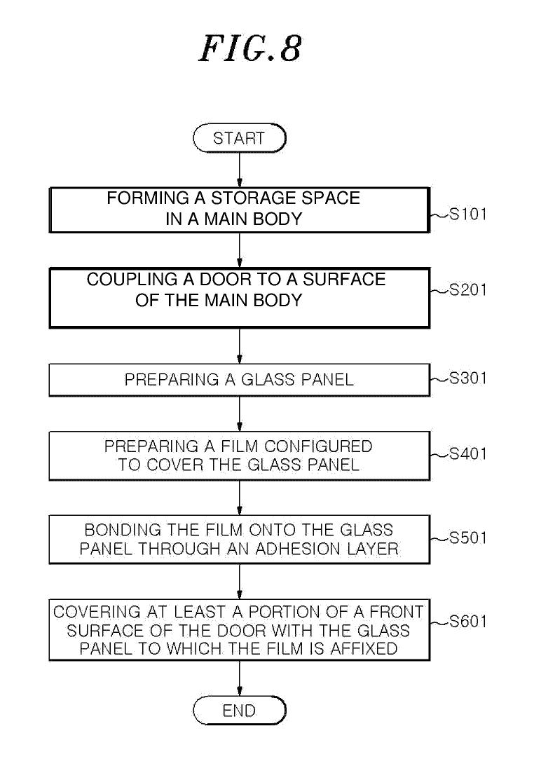

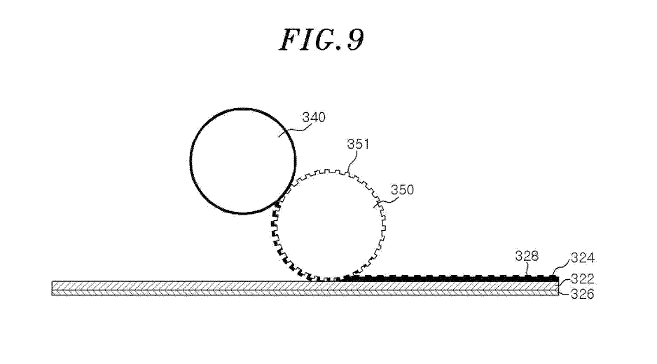

The exemplary method of manufacturing a refrigerator described above will now be described with reference to FIGS. 8 and 9 according to embodiments of the present invention.

FIG. 8 is a flowchart illustrating an exemplary sequence of steps for performing a method for manufacturing a refrigerator (e.g., a refrigerator provided with the glass film member as illustrated in FIG. 7). FIG. 9 is a diagram illustrating an exemplary method of preparing the film of a glass film member (e.g., the glass film member illustrated in FIG. 7).

A storage space is formed in a main body 100 (S101). Then, a door 200 (see FIG. 1) configured to selectively open and close the storage space is coupled to the main body 100 (S201).

To install the door 200, a glass panel 311 is prepared (S301), and the film 321, which covers the glass panel 311, is also prepared (S401).

A step of preparing the film 321 that covers the glass panel 311 will now be specifically described with reference to FIG. 9, according to embodiments of the present invention.

Referring to FIG. 9, the coating layer 324 is disposed on the transparent film layer 322 having the printing layer 326 printed on a lower surface of the transparent film layer 322. For example, the printing layer 326 is printed on a lower surface of the transparent film layer 322 through a gravure printing process, a screen printing process, or the like. The coating layer 324 is disposed on the transparent film layer 322 using an imprinting process, for example.

Specifically, a shaping roller 350 having a shaping-roller-side hair line 351 contacts an ink roller 340, and the ink of the ink roller 340 is transferred to the shaping-roller-side hair line 351. The ink may include, for example, an ultraviolet-curable ink.

The shaping roller 350 is rolled on the transparent film layer 322 and ultraviolet rays are irradiated. As a result, the coating layer 324 having the shaping-roller-side hair line 351 is directly imprinted is disposed on the transparent film layer 322.

The film 321 may then be bonded onto the glass panel 311 using the adhesion layer 316 (S501).

The adhesion layer 315 may include, for example, an ultraviolet-curable resin that is cured by the irradiation of ultraviolet rays to strengthen the adhesion. Thus, as compared with a typical adhesive agent, the adhesion layer 315 is capable of strongly bonding the film 321 to the glass panel 311.

Then, at least a portion of the front surface of the door 200 is covered by the glass panel 311 having the film 321 affixed (S601). In this regard, the glass panel 311 to which the film 321 is affixed refers to the glass film member 301.

Then, the glass film member 301, the side frames 220, the upper cap 230 and the lower cap 240 (see FIG. 2) are fixed to a lower foaming jig (not shown). The liner member 210 is fixed to an upper foaming jig (not shown). The lower foaming jig and the upper foaming jig are coupled together.

A foaming liquid is injected into an internal space between the upper foaming jig and the lower foaming jig. The lower foaming jig and the upper foaming jig are heated. Thereafter, the door 200 is mounted to the main body 100, using a hinge, for example, to couple the door 200 to the main body 100 so that the door 200 can selectively open and close the storage space of the main body 100.

Although exemplary embodiments of the present disclosure are described above with reference to the accompanying drawings, those skilled in the art will understand that the present disclosure may be implemented in various ways without changing the necessary features or the spirit of the present disclosure.

Therefore, it should be understood that the exemplary embodiments described above are not limiting, but only an example in all respects. The scope of the present disclosure is expressed by claims below, not the detailed description, and it should be construed that all changes and modifications achieved from the meanings and scope of claims and equivalent concepts are included in the scope of the present disclosure.

From the foregoing, it will be appreciated that various embodiments of the present disclosure have been described herein for purposes of illustration, and that various modifications may be made without departing from the scope and spirit of the present disclosure. The exemplary embodiments disclosed in the specification of the present disclosure do not limit the present disclosure. The scope of the present disclosure will be interpreted by the claims below, and it will be construed that all techniques within the scope equivalent thereto belong to the scope of the present disclosure.

What is claimed is:

1. A refrigerator comprising:
a main body comprising a storage space;
a door disposed on a surface of the main body and operable to selectively open and close the storage space; and
a glass film member covering at least a portion of a front surface of the door,
wherein the glass film member comprises:
a glass panel;
a protection layer bonded onto the glass panel; and
a film bonded onto the protection layer, wherein the film comprises:
a transparent film layer comprising a pattern formed on a surface of the transparent film layer;
a metal deposition layer deposited on the transparent film layer by filling grooves of the pattern; and
a coating layer disposed on the transparent film layer.

2. The refrigerator of claim 1, wherein the metal deposition layer comprises at least one of titanium and chromium.

3. The refrigerator of claim 1, wherein the coating layer comprises an ultraviolet-curable resin.

4. The refrigerator of claim 1, wherein the glass film member further comprises:
an adhesion layer disposed between the glass panel and the protection layer and operable to bond the glass panel to the protection layer; and
a bonding layer disposed between the protection layer and the film and operable to bond the protection layer to the film, and
wherein the adhesion layer comprises an ultraviolet-curable resin.

5. The refrigerator of claim 1, wherein the door comprises:
a liner member forming a rear surface of the door;
a pair of side frames forming a left side and a right side of the door;
an upper cap forming an upper surface of the door; and
a lower cap forming a lower surface of the door,
wherein an internal space is formed in the door between the glass film member, the liner member, the side frames, the upper cap and the lower cap, and wherein a foaming liquid is injected into the internal space to couple together the glass film member, the liner member, the side frames, the upper cap and the lower cap.

6. A refrigerator, comprising:
a main body comprising a storage space;
a door disposed on a surface of the main body and operable to selectively open and close the storage space; and
a glass film member covering at least a portion of a front surface of the door,
wherein the glass film member comprises:
a glass panel; and
a film bonded to the glass panel, wherein the film comprises:
a transparent film layer;
a printing layer disposed on the transparent film layer; and
a coating layer disposed on the transparent film layer, wherein the coating layer comprises a predetermined pattern disposed on an outer surface of the coating layer.

7. The refrigerator of claim 6, wherein the coating layer comprises an ultraviolet-curable resin.

8. The refrigerator of claim 6, further comprising an adhesion layer disposed between the glass panel and the film and operable to bond the glass panel to the film.

9. The refrigerator of claim 6, wherein the predetermined pattern comprises a hair line pattern.

10. A refrigerator door manufacturing method, the method comprising:
forming a pattern on a transparent film layer;
depositing a metal deposition on the transparent film layer by filling grooves of the pattern;
applying a coating layer onto the transparent film layer;
bonding a protection layer to a glass panel by disposing an adhesion layer between the protection layer and the glass panel;
bonding a film onto the protection layer by disposing a bonding layer between the film and the protection layer; and
covering at least a portion of a front surface of a refrigerator door with the glass panel, wherein the glass panel is coupled to the protection layer and the film.

11. The method of claim 10, wherein the metal deposition layer is formed using at least one of a sputtering process and a vacuum thermal deposition process.

12. The method of claim 10, wherein the coating layer comprises an ultraviolet-curable resin.

13. The method of claim 10, wherein the metal deposition layer comprises at least one of titanium and chromium.

14. A refrigerator manufacturing method, the method comprising;
forming a storage space in a main body; and
coupling a door to the main body, wherein the door is operable to selectively open and close the storage space;
preparing a film configured to cover a glass panel;
bonding the film onto the glass panel by disposing an adhesion layer between the glass panel and the film; and
covering at least a portion of a front surface of the door with the glass panel, wherein the glass panel is coupled to the film, and wherein the preparing the film comprises:
forming a printing layer on a surface of a transparent film layer; and
forming a coating layer on the transparent film layer, wherein the coating layer comprises a predetermined pattern formed on a surface thereof.

15. The method of claim 14, wherein the coating layer is formed by an imprinting process.

16. The method of claim 14, wherein the predetermined pattern comprises a hair line pattern.

17. The method of claim 14, further comprising depositing a metal deposition layer into the predetermined pattern.

18. The method of claim 17, wherein the metal deposition layer comprises at least one of titanium and chromium.

19. The method of claim 14, wherein the coating layer comprises an ultraviolet-curable resin.
